(19) United States
(12) Patent Application Publication
(10) Pub. No.: US 2018/0063967 A1
(43) Pub. Date: Mar. 1, 2018

(54) Interconnections Formed with Conductive Traces Applied onto Substrates Having Low Softening Temperatures

(71) Applicant: Tyco Electronics Corporation, Berwyn, PA (US)

(72) Inventors: Miguel A. Morales, Fremont, CA (US); Leonard H. Radzilowski, Palo Alto, CA (US); Barry C. Mathews, Fremont, CA (US); Michael A. Oar, San Francisco, CA (US)

(21) Appl. No.: 15/249,148

(22) Filed: Aug. 26, 2016

(51) Int. Cl. H05K 3/34; H05K 1/03; H05K 1/11; H05K 1/09; B23K 1/00; B23K 20/00; B23K 35/26; C08J 7/04

(52) U.S. Cl. CPC H05K 3/34; H05K 1/0326; H05K 1/11; H05K 1/032; H05K 1/092; B23K 2201/42; B23K 20/004; B23K 35/262; B23K 35/26; C08J 7/047; H05K 2203/107; B23K 1/0016

(57) ABSTRACT

A method of connecting a wire to a conductive trace formed on a substrate having a predetermined softening point and the functional layered composite formed therefrom. The method comprises applying a conductive ink onto the substrate; curing, drying, or sintering the conductive ink to form the conductive trace with at least one connection pad; applying an activated rosin-type flux and solder to the connection pad and to one end of a metallic wire; placing the end of the wire in contact with the connection pad; applying a source of heat to the wire; melting the solder material to form an interconnection between the wire and the connection pad; removing the source of heat; and allowing the interconnection to cool before moving the wire. The melting point of the solder is either below the softening point of the substrate or above the softening point by about 20° C. or less.

### FIELD

The present disclosure relates to conductive traces formed from metal nanoparticle and/or micro-powder inks applied onto substrates that exhibit a low softening temperature and the use thereof. More specifically, this disclosure relates to interconnections and a method of forming such interconnections with conductive traces applied onto plastic substrates. These conductive traces and substrates may be incorporated into a functional composite and used as part of an electronic component.

### BACKGROUND

The statements in this section merely provide background information related to the present disclosure and may not constitute prior art.

Conductive inks are increasingly being used to form electronic elements, such as antennas, sensors, shielded high-speed connectors, and non-plated electrical contacts, used in a variety of 2-D and 3-D electronic applications. Although the performance of conductive inks in these applications has been encouraging, many hurdles, such as how to interconnect printed elements, remain to be overcome prior to broad acceptance and use of such technology.

Conductive inks may be connected to through the use of mechanical methods, such as spring clips or the like. However, for many applications soldering, which is the most desirable connection method, remains a challenge because the composition and surface of such inks are fundamentally different from conventional printed circuit board (PCB) technology. In addition, silver leaching can occur for printed silver inks when the silver begins to dissolve in molten solder, thereby depleting the silver content and reducing conductivity at the ink-solder interface.

### SUMMARY

The present disclosure generally provides a method of connecting a wire to a conductive trace formed on a substrate and the functional layered composite formed therefrom. The method comprises applying a conductive ink onto a substrate having a predetermined heat deflection temperature, softening point, or melting temperature; curing, drying, or sintering the conductive ink to form the conductive trace with at least one connection pad provided at a predetermined location; applying a flux to the connection pad and to one end of a metallic wire; applying a solder material to the connection pad and to one end of the metallic wire; placing the end of the wire in a location where it makes contact with the connection pad; applying a source of heat to the wire proximate to the location at which the wire contacts the connection pad; melting the solder material to form an interconnection between the wire and the connection pad; removing the source of heat from the interconnection; and allowing the interconnection to cool before moving the interconnected wire. The flux used in the method is a liquid and an activated rosin type. The solder material has a melting point that is either below the heat deflection temperature, softening point, or melting temperature of the substrate or above the softening point by about 20° C. or less.

According to one aspect of the present disclosure, the conductive trace has a metal particle loading of at least 80 wt. % and a thickness that is between about 20 μm to about 100 μm. In addition, the conductive trace exhibits one or more characteristics that include a resistivity of no more than 8.0×10⁻⁵ ohm-cm, a 4B or higher level of adhesion, or heat stability up to a temperature of about 205° C.

According to another aspect of the present disclosure, the conductive ink comprises metal nanoparticles, micro-powders/flakes, or a mixture thereof that have an average particle diameter between about 2 nm and 10 μm. Optionally, one or more of the metal nanoparticles or micropowders is at least partially encompassed with an organic coating. The curing, drying, or sintering of the conductive ink is performed at a temperature that is less than 150° C. for a period of time ranging between about 1 minute and about 90 minutes. The conductive inks and polymer thick film (PTF) pastes may comprise either a thermoplastic binder or a thermoset binder; alternatively, the conductive inks and PTF pastes comprise a thermoplastic binder.

The conductive ink may comprise metal nanoparticles or micro-powder/flakes that are incompletely fused after the drying, curing, or sintering, such that the average particle diameter of the metal nanoparticles or micro-powder/flakes in the conductive trace after the drying, curing, or sintering is substantially the same as that in the conductive ink.

In forming the interconnection, the source of heat makes contact with the wire and the connection pad with an application of no more than 0.5 N force for a period of time that is no longer than 5 seconds. The interconnection that is formed exhibits shear strength at failure of at least 40 N and peel strength at failure of at least 8 N when the interconnected metallic wire is 24 AWG and stranded. In addition, the interconnection exhibits a mechanical strength that is greater than about 80% of the mechanical strength exhibited by the same solder material applied to a molded interconnect device (MID) circuit board using a laser direct structuring (LDS) process.

The solder material used to form the interconnection has a melting point that is less than 150° C. When desirable, the solder material may be a Sn₄₂Bi₅₇Ag₁, Sn₄₂Bi₅₈, Sn₄₈In₅₂, or In₉₇Ag₃ alloy. Alternatively, the solder is Sn₄₂Bi₅₇Ag₁.

The substrate may be without limitation formed from a plastic material that is either amorphous or crystalline. The plastic material may be a polycarbonate, an acrylonitrile butadiene styrene (ABS), a polyamide, a polyester, a polyimide, polyphenylene oxide (PPO), vinyl polymer, polyether ether ketone (PEEK), polyurethane, epoxy-based polymer, polyethylene ether, or polyether imide (PEI). The surface of the substrate may be treated using an atmospheric/air plasma, a flame, an atmospheric chemical plasma, a vacuum chemical plasma, ultraviolet (UV), UV-ozone, heat treatment, solvent treatment, mechanical treatment, or a corona charging process prior to the application of the conductive ink.

According to another aspect of the present disclosure, a functional conductive layered composite may comprise the conductive trace in which at least one interconnection is formed according to the soldering method described above and further defined herein. The functional conductive layered composite may function as an antenna, an electrode of an electronic device, or as an interconnection between two electronic components.

The method of forming the functional conductive layered composite includes connecting a wire to a conductive trace formed on a substrate according to the teachings of the present disclosure, followed by incorporating the conductive trace into the functional conductive layered composite.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

FIG. 1 is a schematic illustration describing a process for forming an interconnection with a conductive ink printed onto a substrate;

FIG. 2 is a scanning electron microscopy (SEM) image of silver micro-powder/flakes in a polymer thick film paste applied onto a polycarbonate substrate after drying, curing, or sintering at 120° C.;

FIG. 3 is a scanning electron microscopy image of the silver nanoparticles in a silver nanoparticle film applied onto a polycarbonate substrate after drying, curing, or sintering at 120° C.;

FIG. 4 is a scanning electron microscopy image of the silver nanoparticles in a silver nanoparticle film applied onto a polycarbonate substrate after drying, curing, or sintering at 180° C.; and

FIG. 5 is a top-down perspective view of Sn₄₂Bi₅₇Ag₁ solder applied to a polymer thick film solder pad to form an interconnection according to the teachings of the present disclosure.

### DETAILED DESCRIPTION

The present disclosure generally relates to forming electrical interconnections to conductive inks that are printed and cured on solid substrates of various material compositions, in particular plastics with relatively low heat deflection, softening, or melting temperatures. The following description is merely exemplary in nature and is not intended to limit the present disclosure, application, or uses. For example, the method made and used in accordance with the teachings contained herein is described throughout the present disclosure in conjunction with polycarbonate substrates commonly utilized in consumer electronic applications in order to more fully illustrate the formation of interconnections to printed conductive films and the use thereof. The incorporation and use of the disclosed method to form interconnections with conductive traces printed on other substrates for use in a variety of applications is contemplated to be within the scope of the present disclosure. It should be understood that throughout the description, corresponding reference numerals or letters indicate like or corresponding parts and features.

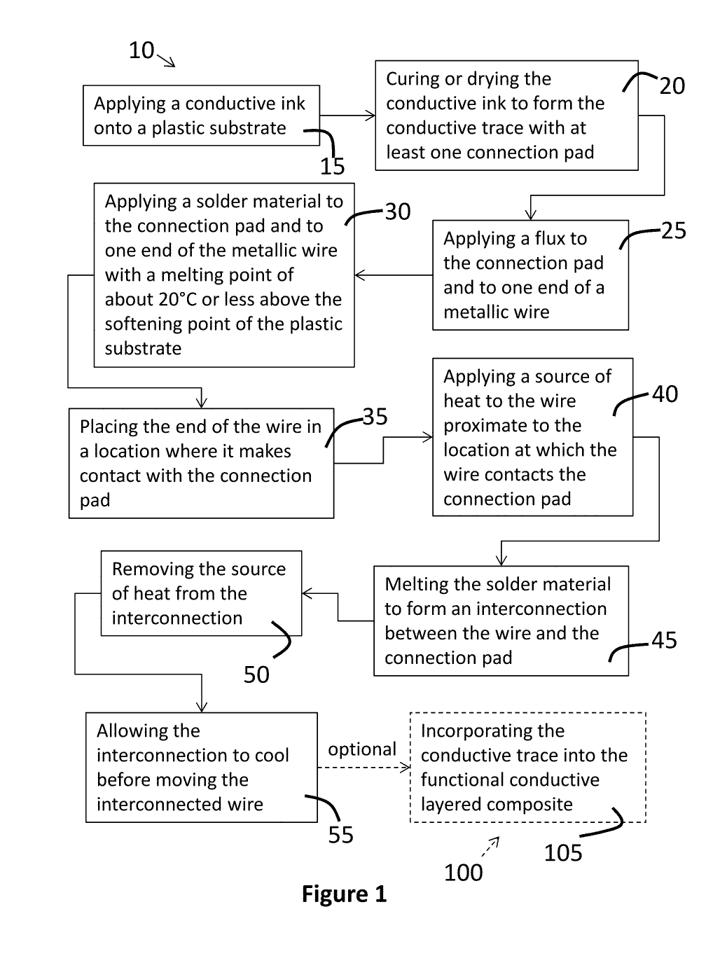

The present disclosure further relates to interconnections made between printed conductive inks and electrical wires using solder. Referring to FIG. 1, the method 10 generally comprises the following steps. First, a conductive ink is applied 15 onto a substrate having a predetermined softening, heat deflection, or melting temperature. The conductive ink is cured, dried, or sintered 20 to form a conductive trace having at least one connection pad. A flux is applied 25 to the connection pad and to one end of a metallic wire. A solder material having a melting point that is either below the heat deflection temperature, softening point, or melting point of the substrate or above the softening point by about 20° C. or less is then applied 30 to the connection pad and to one end of the metallic wire. The end of the wire is placed 35 in a location where it makes contact with the connection pad. A source of heat is applied 40 to the wire proximate to the location at which the wire contacts the connection pad. The solder material is melted 45 to form an interconnection between the wire and the connection pad. The source of heat is then removed 50 from the interconnection. Finally, the interconnection is allowed 55 to cool before moving the interconnected wire.

One benefit of utilizing the method 10 of the present disclosure is to form soldered interconnections that exhibit a mechanical strength which approaches the performance of solder joints made to printed circuit boards and other plastic articles using a conventional molded interconnect device (MID) process, such as laser direct structuring (LDS). The conductive trace to which a wire is to be soldered is formed by drying, curing, or sintering a conductive ink. For the purpose of this disclosure, the term “conductive trace” refers to any conductive elements in any suitable shapes such as a dot, a pad, a line, a layer, and the like. The conductive trace may exhibit one or more characteristics that include a resistivity that is not greater than 8.0×10⁻⁵ ohm-cm and an adhesion rating of 4B or higher as determined according to a standard a tape test, ASTM D3359-09 (ASTM International, West Conshohocken, Pa.), or a heat stability up to a temperature of about 205° C.

Generally, two types of conductive inks, namely, polymer thick film (PTF) pastes or metal nanoparticle inks, as well as a mixture or combination thereof, may be utilized to form the conductive trace. The PTF pastes are composed of micrometer- (i.e. micron-) size metal flakes or powders dispersed in polymer binders. The use of polymer binders allows the cured PTF pastes to adhere to various substrate materials. On the other hand, metal nanoparticle inks are composed of nanometer or nano-size metallic particles. Nanoparticle inks usually do not include a polymer binder, but rather are dispersible in polar solvents, such as, without limitation, an alcohol, water, 1-methoxy-2-propanol (MOP), ethylene glycol (EG), diethylene glycol (DEG), or mixtures thereof.

When desirable, a primer layer may be applied to the surface of the substrate and at least partially cured prior to the application of a nanoparticle ink. In this case, the nanoparticle ink is applied onto the primer layer. The primer layer may be any type of material applied to the surface of the substrate in order to enhance one or more properties associated with the nanoparticle ink, such as but not limited to adhesion. Several specific examples of such a primer layer include without limitation alkoxysilane additives or a poly(vinyl butyral) copolymer.

The metal micro-powders/flakes and nanoparticles present in the ink may comprise, without limitation, silver, copper, gold, aluminum, or a mixture or alloy thereof. Alternatively, the metal micro-powders/flakes or nanoparticles are silver micro-powders/flakes or nanoparticles because they exhibit the highest level of conductivity. When utilized, the PTF pastes may comprise flakes/powders having a size that is within the range of about 1 micrometer (□m) to about 25 μm; alternatively, about 1 μm to about 15 μm; alternatively between about 1 μm to about 5 μm. When utilized, the nanoparticle inks may comprise particles having a size that is within the range of about 2 nanometers (nm) to about 800 nm; alternatively, from about 50 nm to about 800 nm; alternatively, from about 80 nm to about 300 nm. Thus the overall particle size range for the micro-powder/flakes and nanoparticles in the conductive ink is about 2 nm to about 25 μm; alternatively, about 2 nm to about 10 μm; alternatively about 80 nm to about 15 μm.

The metal nanoparticles present in the ink may also optionally comprise an organic coating or a hydrophilic coating, such as a hygroscopic or water-soluble capping agent applied to at least part of the particles' surface. The hygroscopic and/or water-soluble capping agent, may include without limitation, polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof.

The conductive inks can be applied onto the substrate or an optional at least partially cured primer layer using any analog or a digital printing method, including, but not limited to inkjet printing, jet (aerosols and/or fluids) dispense printing, flexographic printing, gravure printing, screen printing, or stencil printing. Other coating methods, including, without limitation, spin coating, dip coating, doctor blade coating, slot die coating can also be used. While analog printing offers high printing speed, digital printing enables the facile change of printed pattern designs, which may find use in the field of personalized electronics. Among the digital printing technologies, jet dispense printing of aerosols and/or fluids is an attractive process due to the large distance between the nozzle and the substrate surface. This characteristic allows conformal deposition of conductive inks on substrates that exhibit a topographic structure. When integrated with a 5-axis motion-control stage or robotic arm, jet dispense heads can be used to print conductive elements onto 3-D surfaces.

The ability to apply the conductive inks to a substrate using a printing technique offers several advantages, such as fast turn-around time and quick prototyping capability, easy modification of device designs, and potentially lower-manufacturing costs due to reducing material usage and the number of manufacturing steps. The direct printing of conductive inks also enables the use of thinner substrates when forming light-weight devices. Printing may also be a more environmentally friendly approach due to the reduced chemical waste generated in the device manufacturing process, when compared to conventional electroplating or electroless plating processes.

The conductive inks exhibit a viscosity that is predetermined by the application process, for example from a few millipascal-seconds (mPa-sec) or centipoise (cps) to about 20 mPa-sec for an inkjet printing process, or from about 50 mPa-sec to about 1000 mPa-sec for aerosol jet, flexographic, or gravure printing processes, or above 10,000 mPa-sec for screen and stencil printing processes. Alternatively, the conductive ink is a nanoparticle ink, which can be printed onto 3-D surfaces using aerosol jet and/or dispense jet printing techniques, or printed onto 2-D surfaces using a screen printing method.

When desirable, the surface of the substrate may be treated using an atmospheric/air plasma, a flame, an atmospheric chemical plasma, a vacuum chemical plasma, UV, UV-ozone, heat treatment, solvent treatment, mechanical treatment, such as roughening the surface with sand paper, abrasive blasting, water jet, and the like, or a corona discharging process prior to the application of the conductive ink or the optional primer layer.

The polymer binder present in the PTF pastes and the capping agent that may be present with nanoparticle inks may limit the temperature that can be reached during the solder process and may also affect solder wetting since some of the metal flakes or particles may be coated by the binder or other organic additives. The polymer binder in the PTF pastes or conductive inks may be either a thermoplastic binder or a thermoset binder. Alternatively, the polymer binder is a thermoplastic binder.

The conductive ink may be cured, dried, or sintered at a temperature equal to or less than 150° C.; alternatively, about 120° C. or less; alternatively, no more than 120° C. The drying, curing, or sintering of conductive ink may occur upon exposure to heat for a period of time ranging from about 1 minute to about 90 minutes; alternatively, for about 2 minutes to about 60 minutes.

The concentration or particle loading of the metal micro-powder/flakes and/or nanoparticles in the conductive ink ranges from about 50 wt. % to about 95 wt. %; alternatively, at least 79 wt. % based on the overall weight of the conductive ink. The thickness of the cured, dried, or sintered conductive trace is greater than about 10 micrometers (μm); alternatively, the thickness may range from about 15 μm to about 500 μm; alternatively, from ˜20 μm to ˜100 μm.

The metal micro-powders/flakes or nanoparticles may be fused together upon annealing at the desired temperature. Alternatively, the metal micro-powder/flakes or nanoparticles may not be entirely fused together, especially at the interface region, when dried, cured, or sintered at the predetermined cure temperature. The cure temperature is determined according to the properties of the substrate or other layers that are pre-deposited on to the substrate. For example, in order to reduce degradation or deformation of a polycarbonate substrate the annealing temperature should be no more than 120° C.

According to some aspects of the present disclosure, a majority of the micro-powder/flakes or nanoparticles are not fused together upon annealing. In these cases, the average particle diameter of the metal flakes or nanoparticles in the conductive trace after annealing is substantially the same as that in the PTF paste or nanoparticle ink. According to other aspects of the present disclosure, a minority of the micro-powder/flakes or nanoparticles are not fused together upon annealing. Alternatively, at least 5 wt. %, alternatively at least 10 wt. %, or alternatively at least 40 wt. % of the micro-powder/flakes or nanoparticles are not fused together. The weight percentage can be measured by extracting the cured, dried, or sintered layer of metal micro-powder/flakes or nanoparticles with a solvent that is compatible with the micro-powder/flakes or nanoparticles and calculating the weight loss.

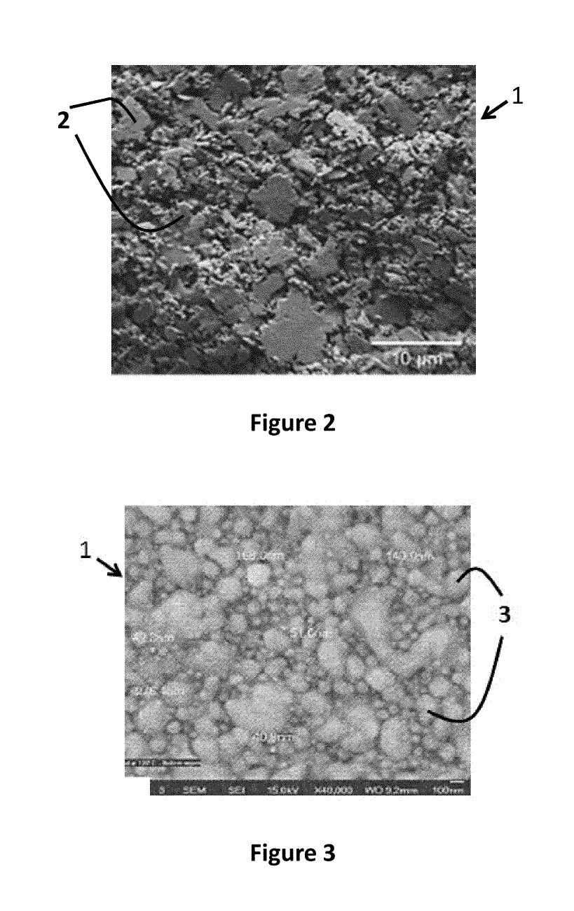

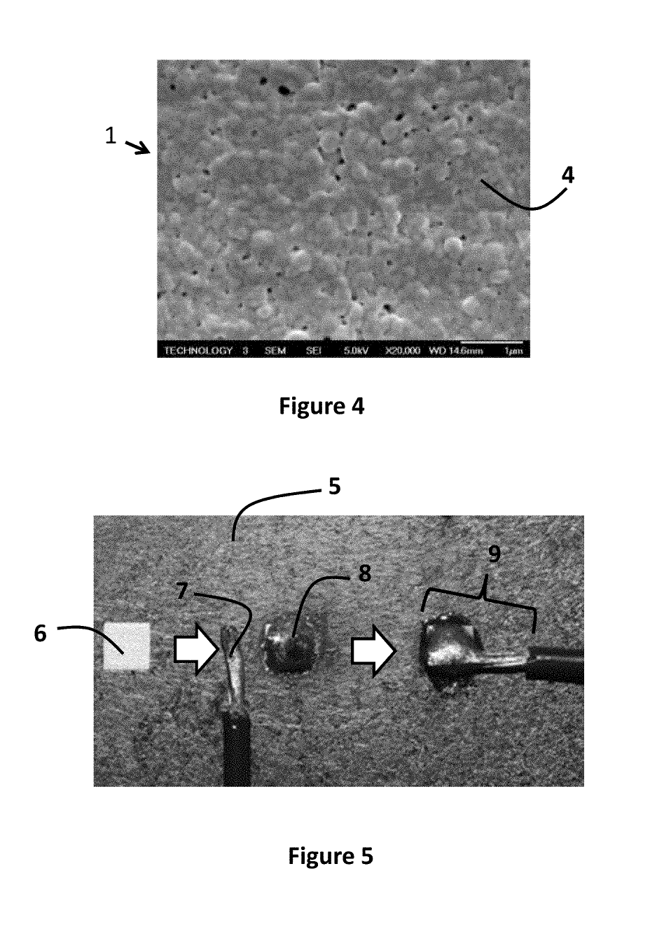

Referring to FIGS. 2 and 3, optical images of a conductive trace 1 formed from a silver PTF paste (FIG. 2) or a silver nanoparticle ink (FIG. 3) after annealing at 120° C. for 60 minutes are provided as obtained by scanning electron microscopy (SEM). Each of the conductive traces 1 was coated onto a polycarbonate substrate. The predetermined temperature to reduce or eliminate degradation and/or deformation of a polycarbonate substrate is 120° C. After curing, drying, or sintering at 120° C. (see FIGS. 2 and 3), a large amount of silver micro-powder/flakes 2 (see FIG. 2) or silver nanoparticles 3 (see FIG. 3) are observed to have distinct boundaries, thereby, demonstrating that individual particles still exist at the interface region. In comparison, in FIG. 4 an SEM image of a conductive trace 1 is shown after being annealed at 180° C., which is above the desired limit for many plastic substrates. In this case, the conductive trace 1 comprises fused silver nanoparticles 4. Thus after annealing at 120° C., the silver nanoparticles 3 in the conductive trace 1 (see FIG. 3) are not entirely fused by exposure to such a low drying or curing temperature. The average particle diameter of the metal powder/flakes or nanoparticles in the dried, cured, or sintered conductive trace formed according to the teachings of the present disclosure is substantially the same as the average particle diameter for the metal powder/flakes or nanoparticles present in the conductive ink.

The substrate material may be amorphous or crystalline. The softening point of an amorphous material is sometimes characterized by its glass transition temperature, T_{g}. A more standardized method for characterizing softening point is deflection temperature, also referred to as deflection temperature under load (DTUL), heat deflection temperature, or heat distortion temperature (HDT), as commonly defined by ASTM D648. For crystalline materials, the softening point is no greater than the melting temperature. Alternatively, the softening point may be equal to the heat deflection temperature, when determined.

The substrate may be without limitation a plastic material. When the substrate is a plastic material, the plastic material may be without limitation, polycarbonate, an acrylonitrile butadiene styrene (ABS), a polyamide, a polyester, a polyimide, polyphenelene oxide (PPO), vinyl polymer, polyether ether ketone (PEEK), polyurethane, epoxy-based polymer, polyethylene ether, polyether imide (PEI), or a copolymer or blend thereof. Specific examples of a polyether imide and a polycarbonate substrate are Ultem™ (SABIC Innovative Plastics, Mass.) and Lexan™ (SABIC Innovative Plastics, Mass.), respectively. Alternatively, the substrate is a polycarbonate or ABS substrate. The substrate may be an unfilled polymer or filled polymer composite, with the amount of filler being predetermined based upon the type of filler used and the composition of the plastic material. For example, plastic materials such as polyphenylene oxide (PPO) can be compounded with as much as 74 wt. % rutile titanium dioxide and successfully soldered to, whereas glass fiber reinforcements incorporated into polycarbonate should be no more than 30 wt. %.

According to one aspect of the present disclosure, the solder may comprise an alloy having a low melting point (MP) formed by combining two or more of the elements, selected from tin (Sn), bismuth (Bi), silver (Ag), lead (Pb), or indium (In). Alternatively, the solder contains silver as one of the elements. Several specific examples of low temperature solder materials include, but are not limited to, Sn₄₂Bi₅₈ (MP=139° C.), In₅₂Sn₄₈ (MP=118° C.), Sn₄₂Bi₅₇Ag₁, (MP=138° C.), Bi_{38.41}Pb_{30.77}Sn_{30.77}Ag_{0.05} (MP=135° C.), Bi₃₆Pb₃₂Sn₃₂Ag₁ (MP=135° C.), In₉₇Ag₃ (MP=143° C.), and In₈₀Pb₁₅Ag₅ (MP=149° C.). Alternatively, the solder is selected from the group of Sn₄₂Bi₅₇Ag₁, Sn₄₂Bi₅₈, Sn₄₈In₅₂, and In₉₇Ag₃; alternatively, the solder is Sn₄₂Bi₅₇Ag₁.

The solder is selected to have a eutectic melting point that is either below the heat deflection temperature, softening point, or melting point of the substrate or above the softening point by approximately 20° C. or less. Alternatively, the solder material has a melting point that is less than 150° C. For example, when the substrate is polycarbonate with softening point of about 130° C., the solder may be selected to be Sn₄₂Bi₅₇Ag₁, which has a eutectic melting point of 138° C. The solder may be used in any form including without limitation a wire, a fiber bundle, a paste, a powder, a foil, or a ribbon; alternatively, the solder is in the form of a wire.

A liquid flux is utilized to assist the flow of the molten metal formed upon heating and to enhance the formation of a better interconnection by reducing the refractory solid oxide layer that resides on the surface of the conductive trace or metal wire. The flux may soften and act as a fluid at a temperature that is equal to or less than the predetermined softening temperature of the substrate. For example, when polycarbonate is utilized as the substrate, the liquid flux may be a resin or rosin flux that tends to soften between 60-70° C. and become a fluid at about 120° C.

Rosin may comprise one or more organic acids, including but not limited to, abietic acid, pimaric acid, isopimaric acid, deoabietic acid, dihydroabietic acid, and dehydroabietic acid. The rosin may be derived from any known source including without limitation, gum rosin (e.g., from pine tree oleoresin), wood rosin (e.g., extracted from tree stumps) or tall oil rosin (e.g., obtained from tall oil). The rosin may comprise natural resins and used as-is or synthetic resins that are modified by esterification, polymerization, or hydrogenation. The rosin may be pure or used with an activator, such as an organic halide salt, a monocarboxylic acid (e.g., formic acid, acetic acid, propionic acid), or a dicarboxylic acid (e.g., oxalic acid, malonic acid, or sebacic acid). The rosin may be stated to be a highly-activated (RA) rosin and exhibit high activity due to the presence of strong activators (e.g., halide salts) or a mildly-activated rosin (RMA) containing mild activators (e.g., no halide salts). A mild flux provides for good heat transfer; while more aggressive fluxes under certain conditions may affect the adhesion of the conductive ink to the substrate. Alternatively, the flux comprises mildly-activated rosin (RMA).

The solder may be melted by the application of a heat source. The heat may be generated using any type of source known to one skilled in the art, including but not limited to, a soldering iron, a laser, or a heat gun. For example, a soldering iron that exhibits a temperature of 205° C.±20° C. can be utilized when Sn₄₂Bi₅₇Ag₁ is utilized as the solder. When using a soldering iron, limiting the time of heat application may help prevent the loss of wetting and possible silver leaching.

Referring again to FIG. 1, the soldering steps in the method 10 include applying 25 a flux to the connection pad of the conductive trace and to one end of a metallic wire. The flux can be applied by dipping the wire and by placing a small drop onto the connection pad. Then the solder material is applied 30 to the connection pad and to the end of the stripped wire. The end of the wire is placed 35 in contact with the connection pad and a source of heat is applied 40. When the source of heat makes contact with the wire and the connection pad, the force applied is no more than approximately 0.5 Newton (N) for no longer than 5 seconds. This amount of pressure is enough to melt the solder within the specified time interval. The use of higher pressure can result in the formation of indentations in a substrate, such as polycarbonate. The heat source is then removed 50 and the interconnection allowed 55 to cool before moving the interconnected wire.

The method 10 of the present disclosure overcomes many hurdles associated with soldering to a printed conductive ink. First, the low-melting point solder allows a joint to be formed without greatly damaging the connection pad, namely, the substrate or the polymer binder present in the PTF ink. Second, silver-containing inks are known to suffer from silver leaching or depletion from the pad-solder-wire interface of the interconnection or solder joint with the use of high temperature solders. No measurable loss of silver is observed at the pad-solder-wire interface to occur using the method of the present disclosure. One skilled in the art will understand that such a loss of silver is measurable because it would manifest itself by causing an increase in the electrical resistance across the solder joint or interconnection.

The mechanical strength of solder joints formed using the method of the present disclosure measures greater than about 80%; alternatively, about 80% to 100%, of the mechanical strength of a solder joint formed with the same solder alloy on a conventional or MID circuit board using a laser direct structuring process. More specifically, the interconnection formed herein exhibits shear strength at failure of at least 40 N and peel strength at failure of at least 8 N when the interconnected metallic wire has a diameter of 0.511 mm (e.g., 24 AWG) and stranded with either a tin (Sn) or silver (Ag) finish.

According to another aspect of the present disclosure, a functional conductive layered composite may be formed that comprises the conductive trace made and treated according to the teachings described above and further defined herein. For the purpose of this disclosure, the term “functional conductive layered composite” refers to any component, part, or composite structure that incorporates the conductive trace. The functional conductive layered composite may function as an antenna, an electrode of an electronic device, or as a means to interconnect or join two electronic components.

Referring once again to FIG. 1, the method 10 may be utilized as part of a method 100 for forming a functional conductive layered composite. The method 100 generally provides performing the method 10 of forming a conductive trace and connecting a wire thereto followed by incorporating 105 the conductive trace into a functional layered composite as defined above.

Within this specification embodiments have been described in a way which enables a clear and concise specification to be written, but it is intended and will be appreciated that embodiments may be variously combined or separated without parting from the invention. For example, it will be appreciated that all preferred features described herein are applicable to all aspects of the invention described herein.

The following specific examples are given to further illustrate the preparation and testing of solder joints or interconnections to conductive traces formed according to the teachings of the present disclosure and should not be construed to limit the scope of the disclosure. Those skilled-in-the-art, in light of the present disclosure, will appreciate that many changes can be made in the specific embodiments which are disclosed herein and still obtain alike or similar result without departing from or exceeding the spirit or scope of the disclosure.

### EXAMPLE 1

### Formation of Interconnections to Conductive Traces

Three commercially-available polymer thick film (PTF) pastes comprising silver micro-powder/flakes were used in Run Nos. 1-3 and a conductive ink comprising silver nanoparticles was utilized in Run No. 4. The PTF paste used in Run Nos. 1 and 2 are of identical chemical composition, with the paste in Run No. 2 having a higher silver content. The PTF silver paste used in Run No. 3 comprises a different binder and solvent composition than the paste used in Run Nos. 1 and 2. The compositions of the various PTF pastes used in the examples are further described in Tables 1 and 2.

Referring now to FIG. 5, each of the conductive inks (Run Nos. 1-4) was printed onto substrates 5 made of different grades of injection molded polycarbonate to form a conductive trace in the shape of a 2 mm×2 mm connection pad 6. The PTF inks (Run Nos. 1-3) were screen printed using standard techniques and also printed with a high-speed jet dispenser (DJ-9500 Dispensejet®, Nordson-Asymtek, Carlsbad, Calif.). The nanoparticle silver ink (Run No. 4) was printed using an Aerosol Jet® 5× system equipped with a Marathon II print module (Optomec Inc., Albuquerque, N.M.). Each of the connection pads 6 was dried, cured, or sintered at 120° C. for 60 minutes.

The wires 7 used for soldering were stranded 24 AWG, either silver or tin coated, and 0.81 mm coaxial cable. Soldering was performed using a hand-held soldering iron set at a temperature of 210° C., a liquid flux, and a tin-bismuth-silver solder alloy 8 in wire form (Sn₄₂Bi₅₇Ag₁, eutectic melting point of 138° C., 0.75 mm wire). The connection pad 6 and wire 7 were first “tinned” by applying flux and solder 8 to each with the iron in contact with the pad. Wire 7 and pad 6 were next joined by laying the iron on the wire while it was in contact with the pad and then cooled to form the interconnection 9.

For comparison, two control interconnections (Control Nos. A and B) were formed by joining a wire to contact pads on a typical FR-4 circuit board (Control No. A) and a laser direct structuring (LDS) grade polycarbonate coupon (Control No. B). The composition of the circuit board pad was a laminate incorporating a copper foil, while the LDS coupon pad was formed from electroless-plated copper with a nickel top layer and a gold surface finish. Both of the pads used in the controls (Control Nos. A and B) had nickel and gold finishes over the copper.

### EXAMPLE 2

### Mechanical Testing of Interconnections

Mechanical testing was performed using a texture analyzer (model TA-XT2, Stable Micro Systems Ltd.), gripping the end of the soldered wire and pulling in either a lap shear configuration or in peel while the substrate was held in a fixture. Additional tests were performed on each sample after exposing the sample to environmental aging conditions. Resistance measurements were made between attached wires and a region of the pads that were not covered with solder.

A summary of the measured data is provided in Table 1 for mechanical tests conducted in a lap shear configuration. When measured in shear with the 24 AWG wire, the interconnections to the polymer thick film inks (Run Nos. 1-3) failed at approximately 50 to 80% of the strength of the control interconnections (Control Nos. A and B). Each reported force value is the average of three identical samples tested for each of the interconnections. The interconnection in Run No. 3 failed at consistently lower values than the interconnections of Run Nos. 1 and 2. All of the solder joints or interconnections for Run Nos. 1-3 failed by cohesion within the connection pad. In comparison, failure occurred within the wire attached to connection pads in Control Nos. A and B. The solder joint to the connection pad formed from the nanoparticle ink (Run No. 4) was also strong enough to cause failure in the attached wire.

TABLE 1

| | | Shear force | Std. | |
|---|---|---|---|---|
| | Pad material | (N) | Dev. | Failure mode |
| Run 1 | DuPont 5025 | 35.6 | 2.4 | Cohesive in pad |
| Run 2 | DuPont 5028 | 42.1 | 3.3 | Cohesive in pad |
| Run 3 | ESL 1908 | 25.3 | 2.1 | Cohesive in pad |
| Run 4 | Paru PG-007 | 52.4 | 0.1 | Wire broke |
| Control A | LDS | 51.9 | 1.4 | Wire broke |
| Control B | PCB | 51.8 | 0.22 | Wire broke |

[Attached wire = stranded 24 AWG; substrate = polycarbonate (PC)].

A summary of the measured data is provided in Table 2 for mechanical tests conducted in a peel configuration. When measured in a peel configuration with the micro-coaxial cable, the attached wire was the shield portion of the 0.81 mm diameter coaxial cable. Each of the shields was “tinned” for each Run No's 1-4 with solder. Solder joints or interconnections to the connection pads formed from the PTF pastes (Run Nos. 1-3) resulted in failure of the coaxial cable with the exception of Run No. 3, which again failed cohesively. Overall the measured peel strength for each of the interconnections was less than the shear strength measured for the interconnections (compare with Table 1) despite the smaller diameter wire. Failure also was observed to occur in the coaxial cable for Control Nos. A and B.

TABLE 2

| | | Peel force | Std. | |
|---|---|---|---|---|
| | Pad material | (N) | Dev. | Failure mode |
| Run 1 | DuPont 5025 | 8.8 | 1.3 | Shield broke |
| Run 2 | DuPont 5028 | 8.4 | 1.4 | Shield broke |
| Run 3 | ESL 1908 | 2.8 | 0.3 | Cohesive in ink |
| Run 4 | Paru PG-007 | 7.9 | 3.2 | 2 of 3 shield broke; 1 of 3 |
| | | | | adhesion to substrate |
| Control A | LDS | 8.2 | 0.4 | Shield broke |
| Control B | PCB | 8.5 | 2.1 | Shield broke |

No interconnections (Run Nos. 1-4) were observed to fail at the ink-solder interface. Although not wanting to be held to theory, it is believed that this behavior indicates that the silver particles in the connection pad are forming a bond to the solder material. This result was obtained despite the observation that solder wetting to the connection pads was qualitatively only “fair” given the rather large contact angle and incomplete coverage that the solder makes with connection pad, as shown in FIG. 5.

The electrical resistance of the solder joint in Run Nos. 1-4 was measured to be approximately 0.1 ohm, which is slightly higher than the electrical resistance measured for the interconnection in Control Nos. A and B. Considering that the connection pads formed from conductive inks (Run Nos. 1-4) have a higher resistance than copper (Control Nos. A and B), the depletion of silver from the interconnection in Run Nos. 1-4 was not appreciable with the soldering technique utilized.

Environmental aging was observed to affect the strength of the interconnection or solder joint as summarized in Table 3 for Run No. 2 and Table 4 for Control No. A. The strength of the solder joint or interconnection in Run No. 2 appears to be degraded to different degrees depending upon the nature of the environmental test condition. The observed failure mode after each aging test was not indicative of failure of the solder itself. Rather, in virtually all tests, the failure occurred by loss of adhesion of the connection pad to the substrate. Thermal shock was the most severe condition and wet heat the least severe condition. The standard deviation of the data was also significantly greater than without aging.

TABLE 3
Run No. 2

| | Shear force | Std. | |
|---|---|---|---|
| Aging test | (N) | Dev. | Failure mode |
| Thermal shock | 30.2 | 17.5 | Adhesive to substrate |
| (−40 to 105° C., 10x) | | | |
| Thermal cycle | 31.9 | 5.6 | Adhesive to substrate |
| (−40 to 105° C., 2 days) | | | |
| Wet heat | 41.2 | 11.2 | Adhesive to substrate |
| (60° C., 90% RH, 1 wk.) | | | |
| Wet cycle | 32.9 | 6.8 | Cohesive ink/Adhesive |
| (23 to 55° C., 95% RH, | | | to substrate |
| 6 days) | | | |
| Salt mist | 32 | 6.3 | Adhesive to substrate |
| (35° C., 5%NaCl, 96 h) | | | |
| NO AGING (Table 1) | 42.1 | 3.3 | Cohesive in pad |

Similar results were observed for the interconnection or solder joint made in Control No. A (see Table 4). Although not wanting to be held to theory, this result may be indicative of the general sensitivity of adhesion to polycarbonate upon environmental exposure of heat and humidity.

### EXAMPLE 3

### Comparison of Solder Performance

A conductive ink was formed by dispersing 57-65 wt. % of silver flakes (Technic Inc., Cranston, Rhode Island) having a particle size between about 2-4 micrometers and about 8-15 wt. % of a thermoplastic resin in diethylene glycol monoethyl ether. The conductive inks were applied to a polycarbonate substrate to form square bond pads, which after solvent evaporation comprised between 79 and 89 wt. % silver. The resistivity of the dried conductive ink with the thermoplastic resin (Run Nos. 5-7) was measured to be no greater than 7.7×10⁻⁵ ohm-cm. A similar square bond pad was made from an identical conductive ink formulation in which the thermoplastic resin was substituted with a thermoset resin (Run No. 8).

A 24 AWG stranded wire was then soldered using a liquid flux to the bond pads according to the procedure described in Example 1 with the soldering temperature being held constant at 204.4° C. The type of solder utilized in each Run No. 5-8 is described in Table 5 below, along with the average shear force (N) encountered before failure was encountered. In all cases shown in Table 5 the failure mode was observed to be cohesive failure of the ink.

TABLE 4
Control No. A

| | Shear force | Std. | |
|---|---|---|---|
| Aging test | (N) | Dev. | Failure mode |
| Thermal shock | 45.8 | 3.3 | Adhesive to substrate |
| (−40 to 105° C., 10x) | | | |
| Thermal cycle | 26.1 | 8.2 | Adhesive to substrate |
| (−40 to 105° C., 2 days) | | | |
| Wet heat | 50.9 | | 2 of 3 failed with no |
| (60° C., 90% RH, 1 wk.) | | | force |
| Wet cycle | 20.7 | 9.5 | Adhesive to substrate |
| (23 to 55° C., 95% RH, | | | |
| 6 days) | | | |
| Salt mist | 46.3 | 3.7 | Adhesive to substrate |
| (35° C., 5%NaCl, 96 h) | | | |
| NO AGING (Table 1) | 51.9 | 1.4 | Wire broke |

This example demonstrates the use of different solders for connecting wires to a conductive ink on a plastic substrate according to the method of the present disclosure. In addition, the use of a thermoplastic resin in the composition of the conductive ink is demonstrated.

TABLE 5

| | | Average | | |
|---|---|---|---|---|
| | | Shear Force | Standard | |
| | Solder Type | (N) | Deviation | Failure Mode |
| Run 5 | Bi₅₇Sn₄₂Ag₁ with | 41.6 | 6.4 | Cohesive ink |
| | thermoplastic resin | | | |
| Run 6 | Bi₅₈Sn₄₂ with | 31.7 | 12 | Cohesive ink |
| | thermoplastic resin | | | |
| Run 7 | In₅₂Sn₄₂ with | 38.7 | 5.8 | Cohesive ink |
| | thermoplastic resin | | | |
| Run 8 | Bi₅₇Sn₄₂Ag₁ with | 41.4 | 7.2 | Cohesive ink |
| | thermoset resin | | | |

The foregoing description of various forms of the invention has been presented for purposes of illustration and description. It is not intended to be exhaustive or to limit the invention to the precise forms disclosed. Numerous modifications or variations are possible in light of the above teachings. The forms discussed were chosen and described to provide the best illustration of the principles of the invention and its practical application to thereby enable one of ordinary skill in the art to utilize the invention in various forms and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method of connecting a wire to a conductive trace, the method comprising:
applying a conductive ink onto a substrate having a predetermined heat deflection temperature, softening point, or melting point;
curing, drying, or sintering the conductive ink to form the conductive trace with at least one connection pad provided at a predetermined location;
applying a flux to the connection pad and to one end of a metallic wire;
applying a solder material to the connection pad and to one end of the metallic wire; the solder material having a melting point that is either below the heat deflection temperature, softening point, or melting point of the substrate or above the softening point by about 20° C. or less;
placing the end of the wire in a location where it makes contact with the connection pad;
applying a source of heat to the wire proximate to the location at which the wire contacts the connection pad;
melting the solder material to form an interconnection between the wire and the connection pad;
removing the source of heat from the interconnection; and
allowing the interconnection to cool before moving the interconnected wire.

2. The method according to claim 1, wherein the conductive trace has a metal particle loading of at least 79 wt. % and a thickness that is between about 20 μm to about 100 μm.

3. The method according to claim 1, wherein the conductive trace exhibits one or more characteristics that include a resistivity not greater than 8.0×10⁻⁵ ohm-cm, a 4B or higher level of adhesion, or a heat stability up to a temperature of about 205° C.

4. The method according to claim 1, wherein the interconnection has a shear strength at failure of at least 40 N and a peel strength at failure of at least 8 N when the interconnected metallic wire is 24 AWG and stranded.

5. The method according to claim 1, wherein the curing, drying, or sintering of the conductive ink is performed at a temperature that is less than 150° C. for a period of time ranging between about 1 minute and about 90 minutes.

6. The method according to claim 1, wherein the source of heat makes contact with the wire and the connection pad with an application of no more than 0.5 N force for a period of time that is no longer than 5 seconds.

7. The method according to claim 1, wherein the interconnection exhibits a mechanical strength that is greater than about 80% of the mechanical strength exhibited by the same solder material applied to a molded interconnect device (MID) circuit board using a laser direct structuring process.

8. The method according to claim 1, wherein the flux being liquid and an activated rosin type, and the solder material has a melting point that is less than 150° C.

9. The method according to claim 7, wherein the solder material is selected as one from the group of Sn₄₂Bi₅₇Ag₁, Sn₄₂Bi₅₈, Sn₄₈In₅₂, and In₉₇Ag₃.

10. The method according to claim 1, wherein the conductive ink comprises metal nanoparticles, micro-powders/flakes, or a mixture thereof that have an average particle diameter between about 2 nanometers and 10 micrometers; optionally, one or more of the metal nanoparticles or micro-powders/flakes is at least partially encompassed with an organic coating.

11. The method according to claim 1, wherein the conductive ink comprises metal nanoparticles or micro-powder/flakes that are incompletely fused after the drying, curing, or sintering, such that the average particle diameter of the metal nanoparticles in the conductive trace after the drying, curing, or sintering is substantially the same as that in the conductive ink.

12. The method according to claim 1, wherein the conductive ink comprises a thermoplastic binder or a thermoset binder.

13. The method according to claim 12, wherein the conductive ink comprises a thermoplastic binder, and the solder is selected as one from the group of Sn₄₂Bi₅₇Ag₁, Sn₄₂Bi₅₈, Sn₄₈In₅₂, and In₉₇Ag₃.

14. The method according to claim 12, wherein the conductive ink comprises a thermoset binder, and the solder is Sn₄₂Bi₅₇Ag₁.

15. The method according to claim 1, wherein the substrate is a plastic substrate formed from a polycarbonate, an acrylonitrile butadiene styrene (ABS), a polyamide, or a polyester, a polyimide, polyphenylene oxide (PPO), vinyl polymer, polyether ether ketone (PEEK), polyurethane, epoxy-based polymer, polyethylene ether, polyether imide (PEI).

16. The method according to claim 1, wherein the method further comprises treating the surface of the substrate using an atmospheric/air plasma, a flame, an atmospheric chemical plasma, a vacuum chemical plasma, UV, UV-ozone, heat treatment, solvent treatment, mechanical treatment, or a corona charging process prior to the application of the conductive ink.

17. A functional conductive layered composite comprising the conductive trace having at least one interconnection formed according to the method of claim 1.

18. A method of forming a functional conductive layered composite comprising:
applying a conductive ink onto a substrate having a predetermined heat deflection temperature, softening point, or melting point;
curing, drying, or sintering the conductive ink to form a conductive trace with at least one connection pad provided at a predetermined location;
applying a flux to the connection pad and to one end of a metallic wire; the flux being liquid and an activated rosin type;
applying a solder material to the at least one connection pad and to one end of a metallic wire; the solder material having a melting point that is either below the heat deflection temperature, softening point, or melting point of the substrate or above the softening point by 20° C. or less;
placing the end of the wire in a location where it makes contact with the connection pad;
applying a source of heat to the wire proximate to the location at which the wire contacts the connection pad;
melting the solder material to form an interconnection between the wire and the connection pad;
removing the source of heat from the interconnection;
allowing the interconnection to cool before moving the interconnected wire; and
incorporating the conductive trace into the functional conductive layered composite.

19. The method according to claim 18, wherein the source of heat makes contact with the wire and the connection pad with an application of no more than 0.5 N force for a period of time that is no longer than 5 seconds.

20. The method according to claim 18, wherein the conductive trace has a metal particle loading of at least 79 wt. %, a thickness that is between about 20 μm to about 100 μm; and
exhibits one or more characteristics that include a resistivity no more than 8.0×10⁻⁵ ohm-cm, a 4B or higher level of adhesion, or a heat stability up to a temperature of about 205° C.

21. The method according to claim 18, wherein the interconnection has a shear strength at failure of at least 40 N and a peel strength at failure of at least 8 N when the interconnected metallic wire is 24 AWG and stranded.
